(19) United States
(12) Patent Application Publication
(10) Pub. No.: US 2010/0212718 A1
(43) Pub. Date: Aug. 26, 2010

(54) Optical Waveguide based Solar Cell and methods for manufacture thereof

(75) Inventor: Conrad Edward Houghton, McKinney, TX (US)

Correspondence Address: Conrad Edward Houghton, 4421 Cordova Lane, McKinney, TX, 75070, US

(73) Assignee: BolCon Technologies LLC

(21) Appl. No.: 12/636,498

(22) Filed: Dec. 11, 2009

Related U.S. Application Data
(60) Provisional application No. 61/154,953, filed on Feb. 24, 2009.

(51) Int. Cl. H01L 31/055; H01L 31/00

(52) U.S. Cl. 136/246; 136/259

(57) ABSTRACT

A more efficient design for a solar cell based upon an optical waveguide along with cost effective methods for manufacturing the new solar cell. The optical waveguide based solar cell achieves an increase in efficiency through the use of a three dimensional geometry. In general terms, an inwards facing solar cell is wrapped around the length of an optical waveguide which then uses the end of the waveguide to capture the light and feed it in towards the lengthy solar cell.

### CROSS REFERENCE TO RELATED APPLICATION

This application claims the benefit of U.S. Provisional Application No. 61/154,953 filed on Feb. 24, 2009. The entire disclosure of that application is incorporated herein by reference.

### REFERENCES CITED

1. U.S. Pat. No. 6,091,015 Jul. 18, 2000 del Valle, et al. Photovoltaic energy supply system with optical fiber for implantable medical devices
2. U.S. Pat. No. 6,913,713 Jul. 5, 2005 Chittibabu, et al. Photovoltaic fibers
3. Elizabeth Corcoran “A Trick of the Light”, Forbes, Sep. 3, 2007, pp. 92-94.
4. United States Patent Application 2009/0103859 Apr. 23, 2009 Shtein, et al. FIBER-BASED ELECTRIC DEVICE
5. Benjamin Weintraub, Yaguang Wei, and Zhong Lin Wang, “Optical Fiber/Nanowire Hybrid Structures for Efficient Three Dimensional Dye Sensitized Solar Cells”, Angewandte Chemie Int. Ed. 2009, 48, 1-6, Received for publication Aug. 12, 2009.

### BACKGROUND OF INVENTION

The field of endeavor to which this invention pertains is the production of electricity by means of the photovoltaic (PV) type solar cell. It is the object of the invention to improve upon existing solar cell designs by increasing their efficiency in converting light into electricity as well as offering a means to lower the cost of their manufacture.

### BACKGROUND ART

While solar cells have been around for over a century, their use as a means to generate electricity for residential, commercial, and utility purposes has been limited to date by their high up front costs in comparison to fossil fuel based thermoelectric power plants used for grid electrical generation. While the direct generation of electricity from sunlight has a number of benefits, the current technology of solar cells has a number of problems which prevent it from being cost competitive with grid based electrical power produced from fossil-fuels.

Problems with existing solar cells:
1) Existing solar cells are inefficient at converting all of the light received upon their surface capture into electricity. There are a number of solar cell technologies in manufacture today that attempt to address this problem but the goal of converting greater that 25% of the energy in light striking the solar cell to electricity, has not yet to be met outside the lab. There are a number of long-term research efforts aimed at addressing this limitation, primarily through the use of exotic materials such as nanotubes or organic compounds, but they remain years away from commercial deployment.
2) The current large scale production of photovoltaic solar cells is relatively costly when compared to non-solar electrical production means. The lowest cost photovoltaic solar cells in widespread production today are those that use thin film production processes. Thin film based solar cells are currently less than half as efficient as crystalline Silicon based solar cells, which in turn results in a higher Levelized Cost Of Electricity in a functioning solar array. In simple terms, if a solar array needs twice as much surface area to produce the same given amount of electricity, then this adds significantly to system costs.
3) It is difficult to integrate the existing solar cell designs into applications that can be used for building integrated photovoltaic's (BIPV). Crystalline wafer based Silicon solar cells are fragile and require a relatively heavy protective glass coating to provide the necessary rigidity and strength.

### BRIEF SUMMARY OF INVENTION

It is the objective of the present invention to provide an Optical Waveguide based Solar Cell of increased efficiency and cost effective methods of manufacture of these new solar cells made through the use of this invention.

### BRIEF DESCRIPTION OF THE SEVERAL VIEWS OF THE DRAWING

FIG. 1 is an orthogonal view of a standard crystalline Silicon based solar cell in manufacture at this time. This is shown as prior art.

FIG. 2 is an orthogonal view of the new Optical Waveguide based Solar Cell showing the advantages of its new geometry.

FIG. 3 is a functional view of an existing type of thin film amorphous Silicon based solar cell. It is shown as prior art.

FIG. 4a is an orthogonal view of an Optical Waveguide based Solar Cell made using thin film amorphous Silicon and employing a Transparent Conductive Oxide on its innermost conductive layer. The Solar Cell is shown in a cut away view to reveal the different functional layers.

FIG. 4b is an end view of an Optical Waveguide based Solar Cell employing thin film amorphous Silicon and a Transparent Conductive Oxide on the innermost conductive layer.

FIG. 4c is a an orthogonal view of an Optical Waveguide based Solar Cell employing thin film amorphous Silicon and a wire mesh for the innermost conductive layer. The Solar Cell is shown in a cut away view to reveal the different functional layers.

FIG. 5 is an orthogonal view showing how a classic solar cell captures sunlight in two dimensions. It is shown as prior art.

FIG. 6 is an orthogonal view showing how an Optical Waveguide based Solar Cell uses three dimensions to capture sunlight.

FIGS. 7a, 7b, and 7c are orthogonal views showing how the Optical Waveguides, used in this new Solar Cell, may vary in depths and thicknesses. The view shows three individual Optical Waveguides bundled together.

FIGS. 8a, 8b, and 8c are orthogonal views of the different shapes for the Optical Waveguide used as the core of the new Solar Cell.

FIGS. 9a and 9b are orthogonal views of the packing arrangements of the Optical Waveguides used in the new Solar cell. In FIG. 9a, three Optical Waveguides have been bundled together.

FIGS. 10a and 10b are orthogonal views of a flat Optical Waveguide based Solar Cell.

FIG. 11 is a functional diagram of how a single band Optical Waveguide based Solar Cell would be produced in a continuous process of manufacture.

FIG. 12 is orthogonal view of the manufactured single band Optical Waveguide based Solar Cell before it has been cut into individual solar cell lengths.

FIG. 13a is a functional view of how six Optical Waveguide based Solar Cells, plus reinforcing materials and electric conductors would be woven into a fabric.

FIG. 13b is an orthogonal view of the output of the process of weaving six Optical Waveguide based Solar Cells in combination with wire conductors as well as other fibers added for structural strength. The view is slightly exploded for clarity since spacing between the Optical Waveguide based Solar Cells would be very tight.

FIGS. 14a and 14b are orthogonal views of the final assembly used to convert individual Optical Waveguide based Solar Cells into modules.

FIG. 15 is an orthogonal view showing how a fisheye type lens might be used to concentrate Sunlight, that is received at different angles of incidence, into the transparent end of the Optical Waveguide based Solar Cell.

FIG. 16 is an orthogonal view of an Optical Waveguide based Solar Cell employing a two junction thin film photovoltaic semiconductor design. The Solar Cell is shown in a cut away view to reveal the different functional layers.

FIG. 17 is an orthogonal view of an Optical Waveguide based Solar Cell that uses two different bands of Photovoltaic materiel.

FIG. 18 is an orthogonal view showing how prismatic lens might be used to focus portions of the sunlight onto different bands of photovoltaic material within a two band Optical Waveguide based Solar Cell.

FIG. 19 is functional diagram of how Optical Waveguide based Solar Cells could be manufactured using a flexible flat substrate.

### DETAILED DESCRIPTION OF THE INVENTION

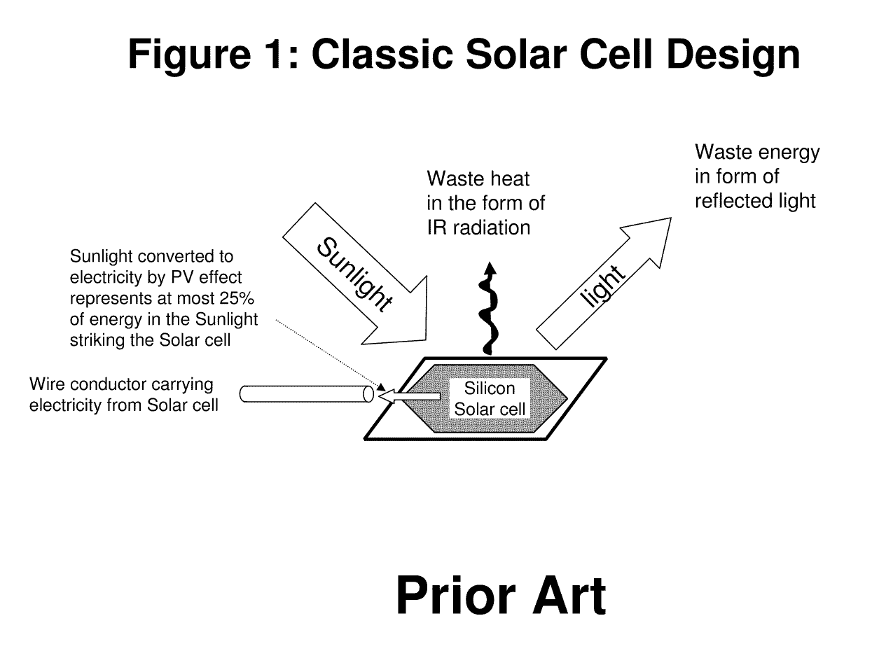

In FIG. 1, a classic Silicon based solar cell is shown as an example of prior art. This figure is intended to illustrate one of the key problems solar cells which is the inefficiency with which it converts Sunlight striking the surface capture area into electricity. Solar cells in manufacture today have trouble achieving 25% efficiency in the conversion of the light energy into electricity. The 25% efficiency is barely achievable using wafer based crystalline Silicon technology which must be produced using batch methods due to the requirement for very high purity of the Silicon semiconductor.

The more easily produced thin film amorphous Silicon solar cells, can be made in a continuous production method using Silicon with lower purity but these solar cells are significantly less efficient than those made with crystalline Silicon.

One of the reasons for the inefficiency of classic solar cells is the fact that significant portion of the light striking the capture surface, and which does not get converted to electricity, is reflected away and lost to further use.

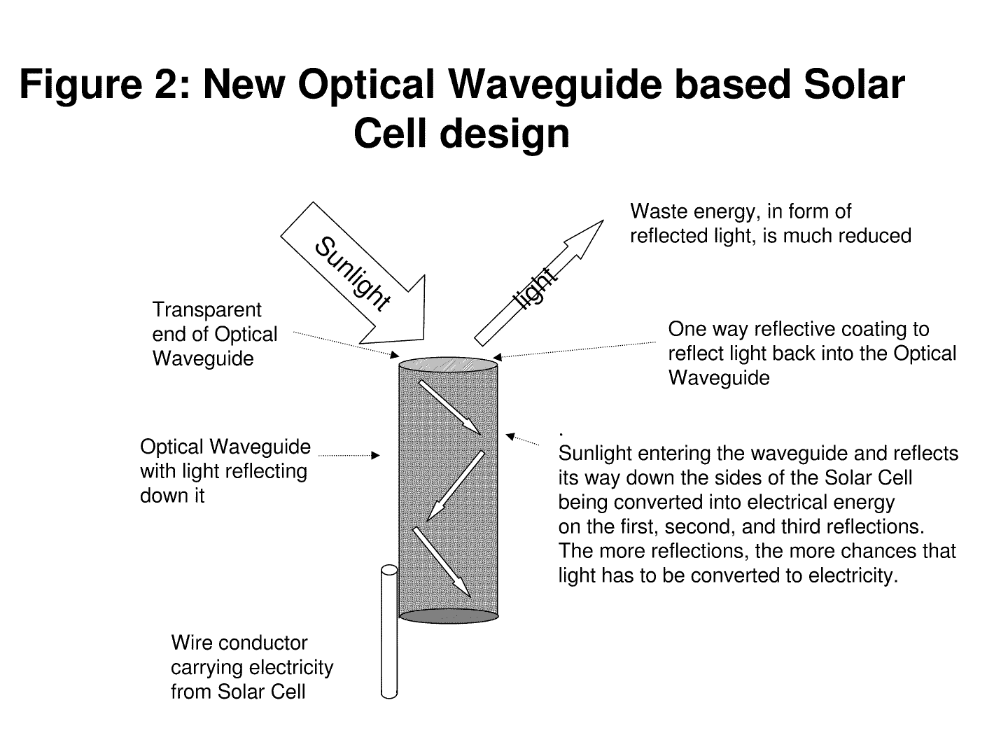

In FIG. 2, a design for new Optical Waveguide based Solar Cell is shown. Sunlight striking the transparent end of the Optical Waveguide, enters inside where it strikes the photovoltaic materials lining the Optical Waveguide. The light is either converted to electricity or it is reflected. The reflected light travels further down the Optical waveguide where it has multiple opportunities to strike photovoltaic material and get converted into electricity. The photovoltaic material is inwards facing towards the Optical Waveguide which is transmitting the sunlight received from the surface capture area. Effectively, in an Optical Waveguide based Solar Cell, the solar cell is turned inside out and wrapped around a transparent core. Unlike a classic solar cell, the light reflected deeper in the solar cell is converted rather than wasted.

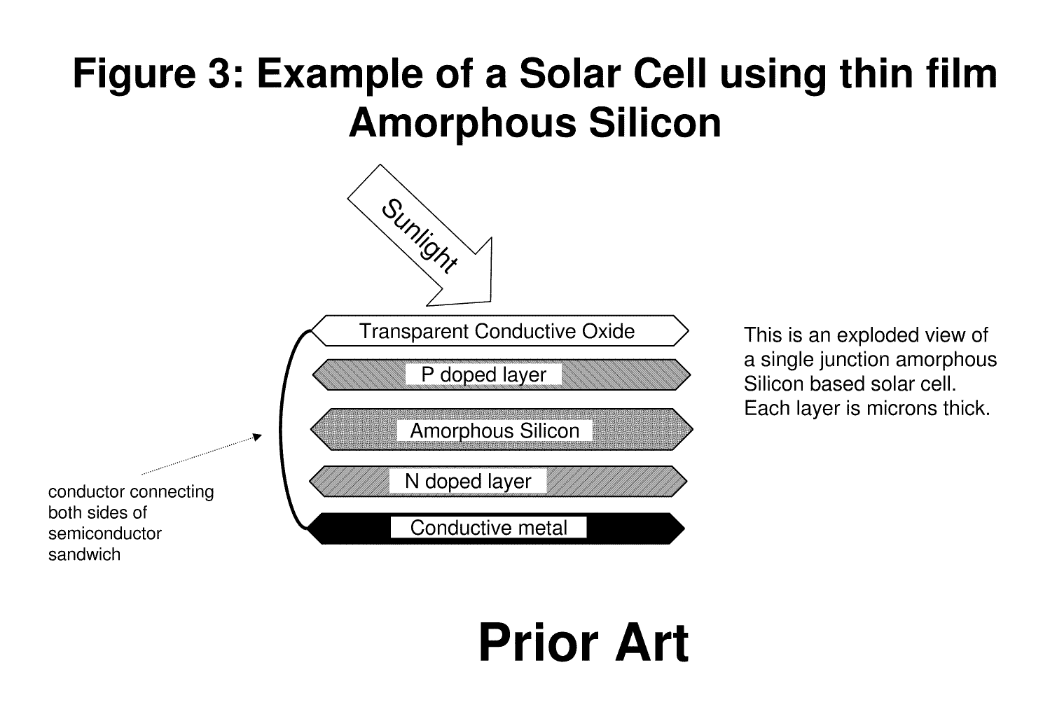

In FIG. 3, a functional diagram of an existing solar cell based upon thin film amorphous Silicon is shown. This is shown prior art. It illustrates the key functional components of a semiconductor based photovoltaic. These same components are re-used in a novel fashion by the Optical Waveguide based Solar Cell.

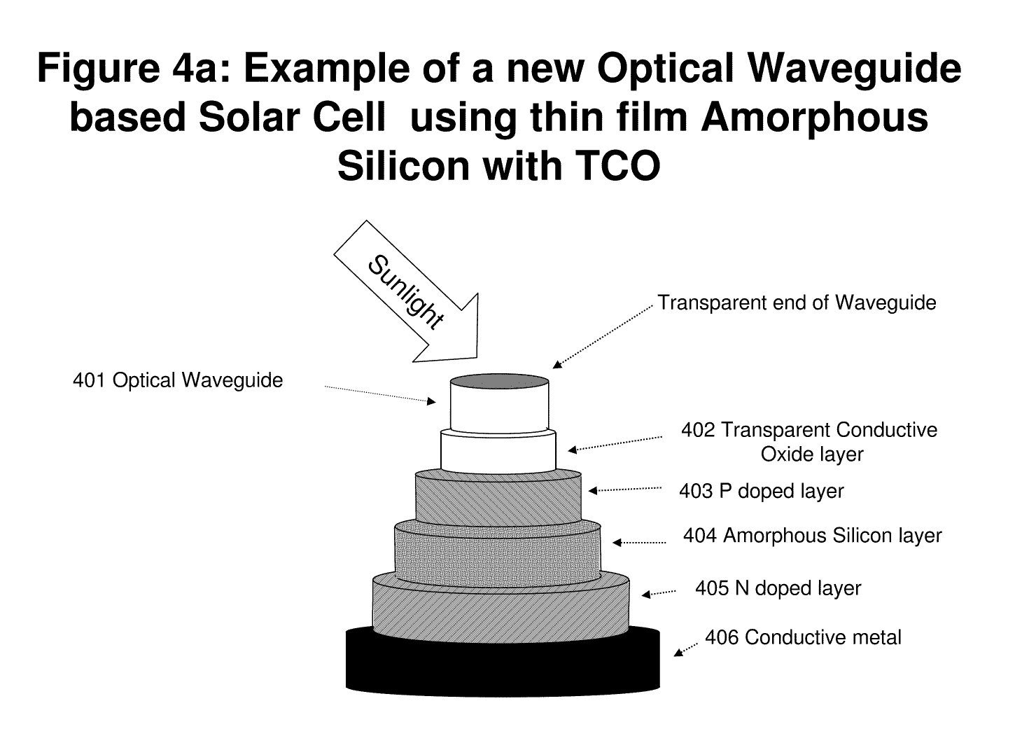

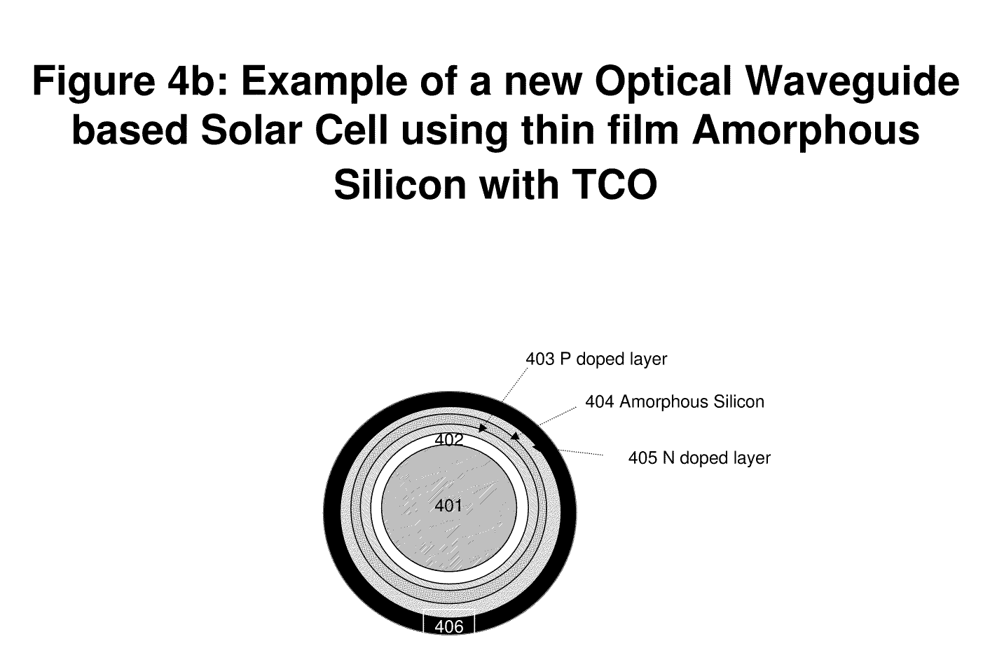

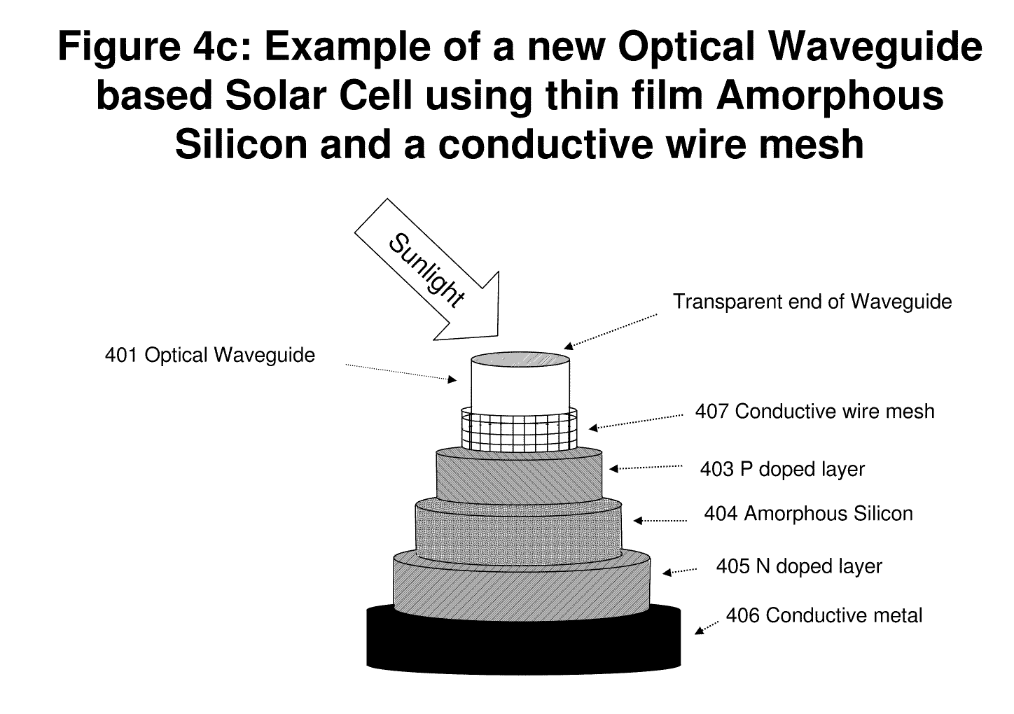

In FIGS. 4a, 4b, and 4c, an example of an Optical waveguide based Solar Cell employing thin film amorphous Silicon technology is shown. The cut away view in FIG. 4a shows the different layers of materials that make up the Solar Cell. The differing photovoltaic materials (the semiconductor sandwich and associated conductors) are shown wrapped circumferentially around an Optical Waveguide identified as 401.

The Optical Waveguide (401) is cylindrical in this example, although any shape with the necessary properties to function as an optical waveguide could be used.

The first conductive layer (402), that which is closest to the Optical Waveguide, is a Transparent Conductive Oxide (TCO). The requirement is for a conductive layer that does not block the light from striking the semiconductor behind it. This can be achieved by use of a Transparent Conductive Oxide or through use of a conductive wire mesh (407). In FIGS. 4a and 4b a the first conductive layer is a TCO. In FIG. 4c, the first conductive layer is made up of a conductive wire mesh (407) similar to what is used today on a crystalline solar cell, for example it could use a tree trunk and branch geometry to reduce the shading of the semiconductor below it. The wire mesh would benefit from being made of a reflective material since the Optical Waveguide based Solar Cell can take advantage of reflected light by converting it to electricity deeper within the Solar Cell.

The next layer (403) is the P doped layer of the Silicon semiconductor. The choice of a P doped layer or a N doped layer in this position immediately on top of the first conductive layer will vary based upon the particular solar cell design. What will not vary is the fact that the semiconductor will be sandwiched between a P doped layer and a N doped layer.

The next layer (404) is a layer of amorphous Silicon. In this example Optical Waveguide based Solar Cell a design based upon amorphous Silicon was used. The Solar Cell could equally be manufactured using a different photovoltaic semiconductor material such as Copper Indium Diselenide (CIS).

The next layer (405) is the N doped layer of Silicon. The choice of a N doped layer or a P doped layer in this position immediately on top of the first conductive layer will vary based upon the particular solar cell design. What will not vary is the fact that the semiconductor will be sandwiched between a P doped layer and a N doped layer.

The next layer (406) is a conductive metal layer. A metal conductor was chosen for this layer but any conductive material that provides a better conductive path than the semiconductor would do. The two conductive layers 402 and 406 are connected physically to provide an electrical path that supports the photovoltaic effect that occurs when sunlight strikes the semiconductor sandwich. This completes the electrical circuit in the Solar Cell design.

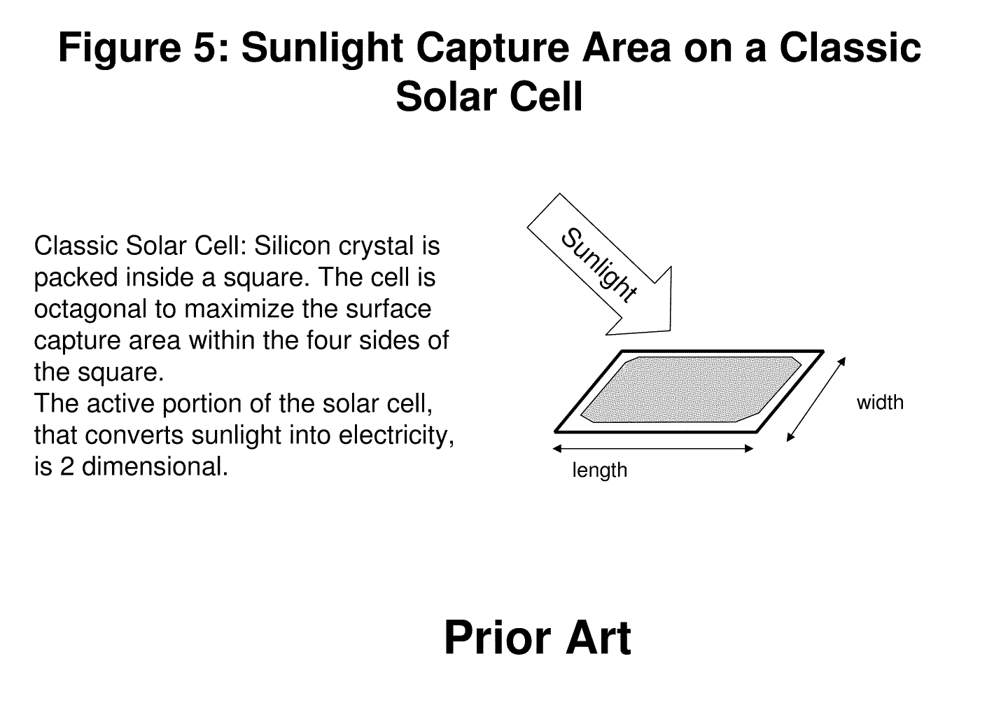

FIG. 5 is shown as an example of prior art. It illustrates one of the key limitations of classic solar cell design namely the fact that it is almost entirely two dimensional. The classic solar cell basically gets one try at converting light that strikes its capture surface. The element of depth, in a classic Solar Cell, is confined to the thickness of the photovoltaic semiconductor sandwich.

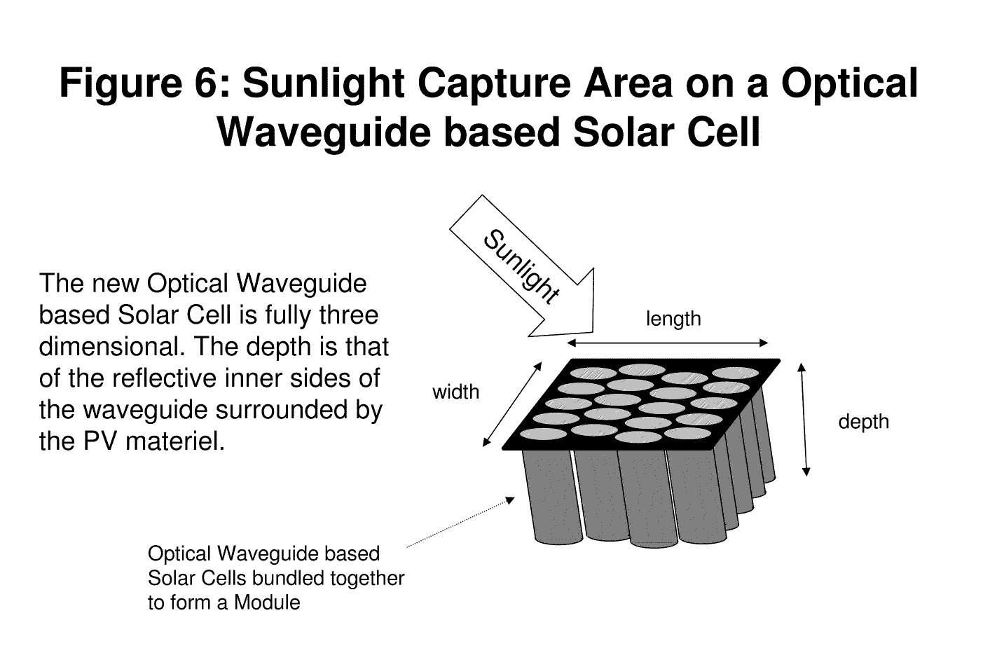

FIG. 6 shows a Solar Cell module based upon individual Optical Waveguide based Solar Cells. Sunlight strikes the two dimensional surface capture area but enters into the transparent ends of the Optical Waveguides. Sunlight is converted into electricity upon directly striking the photovoltaic material surrounding the inside of the Optical Waveguide or it is reflected further to strike another photovoltaic surface where it can be converted into electricity. The Optical Waveguide based Solar Cell is fully three dimensional and takes advantage of the depth to extend the opportunity to convert light into electricity.

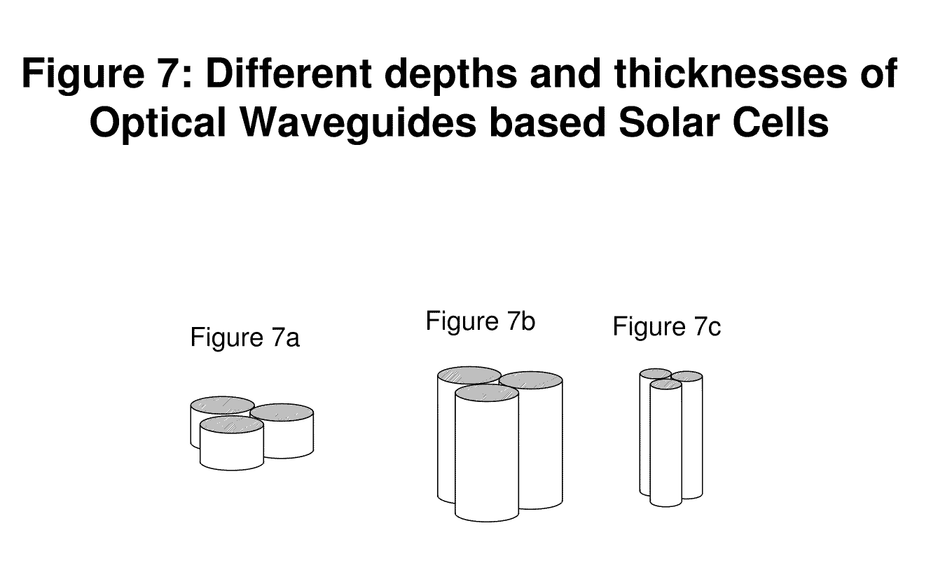

FIGS. 7a, 7b, and 7c show different depths and thicknesses of Optical Waveguides. These three figures show three Optical Waveguides bundled together because a typical Solar Cell module design would likely use multiple Optical Waveguide based Solar Cells. The optimal thickness of the Optical Waveguide will be determined based upon the final Solar Cell design. It could be a micrometer thick fiber strand or a centimeter thick tube. Different types of solar cells, that were made for different applications, would use a thickness of the Optical Waveguide that was optimized for their design requirements. The particular requirements of an individual Solar Cell design will balance the structural needs, for example, thin glass fibers may be stronger versus the manufacturing requirements where it may be cheaper to coat a thicker glass strand with photovoltaic material during manufacture.

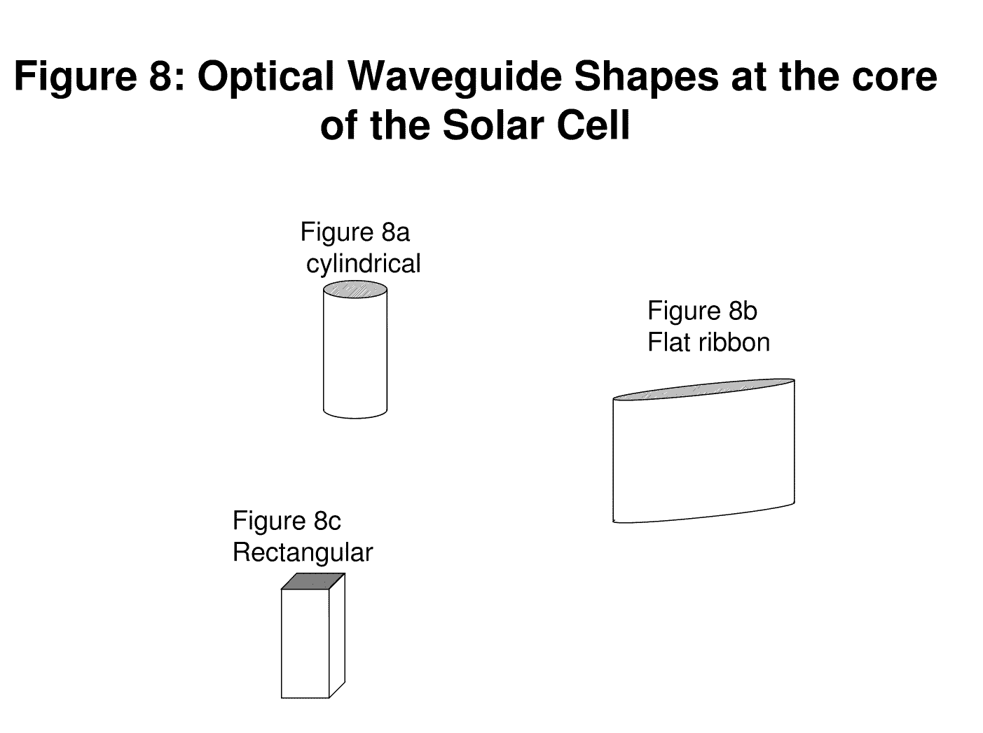

FIGS. 8a, 8b, and 8c show different shapes for the Optical Waveguide used in the new Solar Cell. In FIG. 8a, a cylindrical Optical Waveguide profile is shown. In FIG. 8b, an Optical Waveguide with a flat ribbon like profile is shown. In FIG. 8c, a rectangular shaped Optical waveguide profile is shown. The Optical Waveguide can be composed of various different shapes as long as it functions i.e. supports the transmission of light. The particular shape of the Optical Waveguide will depend upon the particular design requirements for the Solar Cell.

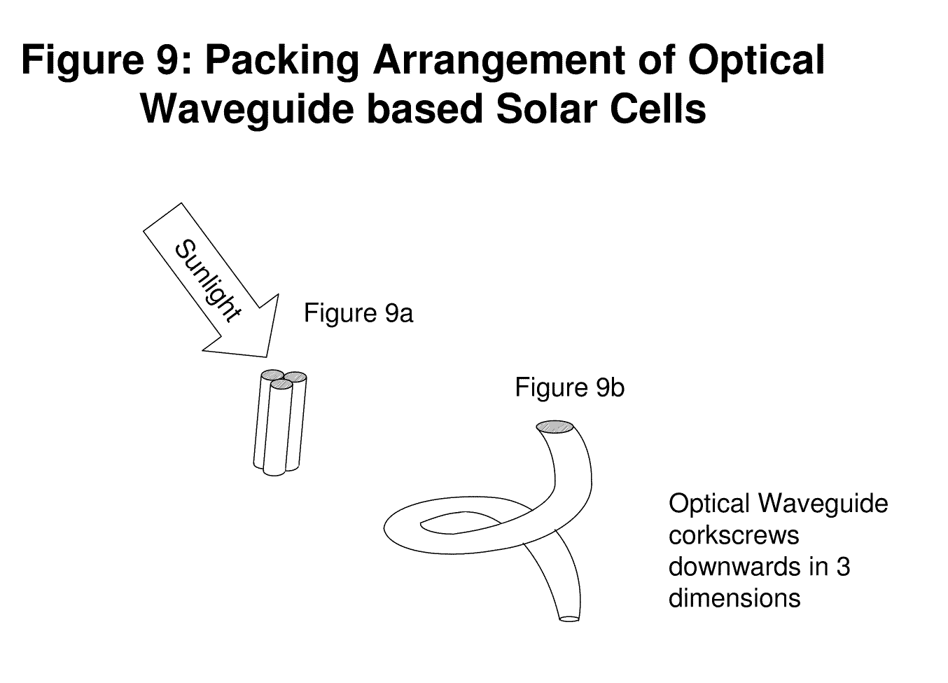

FIGS. 9a and 9b show different arrangements for packing the Optical Waveguides. The FIG. 9a shows three Optical Waveguides bundled together in an example Solar Cell design. In this example, the Optical Waveguides lie at an angle off the perpendicular to the top surface that captures the sunlight. The Optical Waveguides can lie a various angles ranging from perpendicular to near horizontal subject to the requirements of capturing incoming Sunlight and subject to the physical limitations of the materials used in the Solar Cell design. One possible benefit of using Optical Waveguides at an angle to the perpendicular, includes creating a slightly thinner overall solar cell. Another benefit to using angled Optical Waveguides is that sunlight received directly at 90 degrees from the perpendicular, will not travel too far down the Optical Waveguide before striking the photovoltaic material where it can be converted to electricity or reflected further down the waveguide for later conversion.

FIG. 9b shows an example of a Optical Waveguide that corkscrews downwards in three dimensions. It could be bundled with other Optical Waveguides to form a Solar Cell. The Optical Waveguides could be twisted around each other like a rope composed of individual strands. One possible benefit to having Optical Waveguides bundled in a corkscrew arrangement is a stronger structure could be assembled using this arrangement when combined with a suitable resin based bonding system. The packing arrangement of the Optical Waveguides will be based upon the final Solar Cell design requirements. Ideally the ends of the Optical Waveguides must be arranged so as to maximize the capture of the light entering the Waveguide to be converted to electricity by the photovoltaic material lining the Waveguide. Another benefit in using a non straight Optical Waveguide, is that this increases the probability of the incoming light striking the side of the Optical Waveguide where it can be converted by the photovoltaic materiel. The overall depth of the Solar Cell design could thus be reduced.

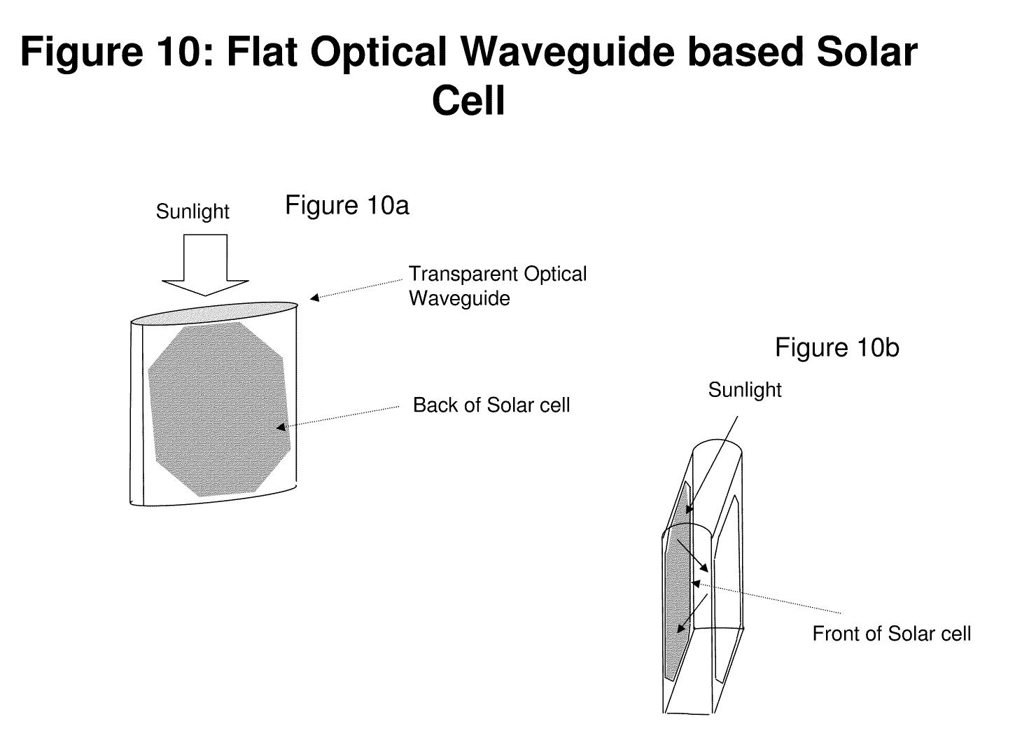

FIGS. 10a and 10b show an example of a flat Optical Waveguide based Solar Cell made with an inflexible photovoltaic material like wafer based crystalline Silicon. Unlike the basic design of the Optical Waveguide based Solar Cell described in FIG. 4, this Solar Cell design does not use a continuous band of photovoltaic materials completely encircling the Optical Waveguide. Instead, it uses two inwards facing Solar cells that sandwich the Optical Waveguide core. The capture surface is the edge of the Optical Waveguide which would be facing towards the source of light. Sunlight would enter the Optical Waveguide and strike the photovoltaic materials where it would be converted into electricity or reflected to be possibly converted the next time it strikes another photovoltaic surface. Any portion of the interior of the Optical Waveguide, that is not in direct contact with the photovoltaic material, would be made reflective to increase the overall efficiency. In other words, the light would be reflected back inside so it can be converted later when it finally strikes the solar cell inside the Optical Waveguide.

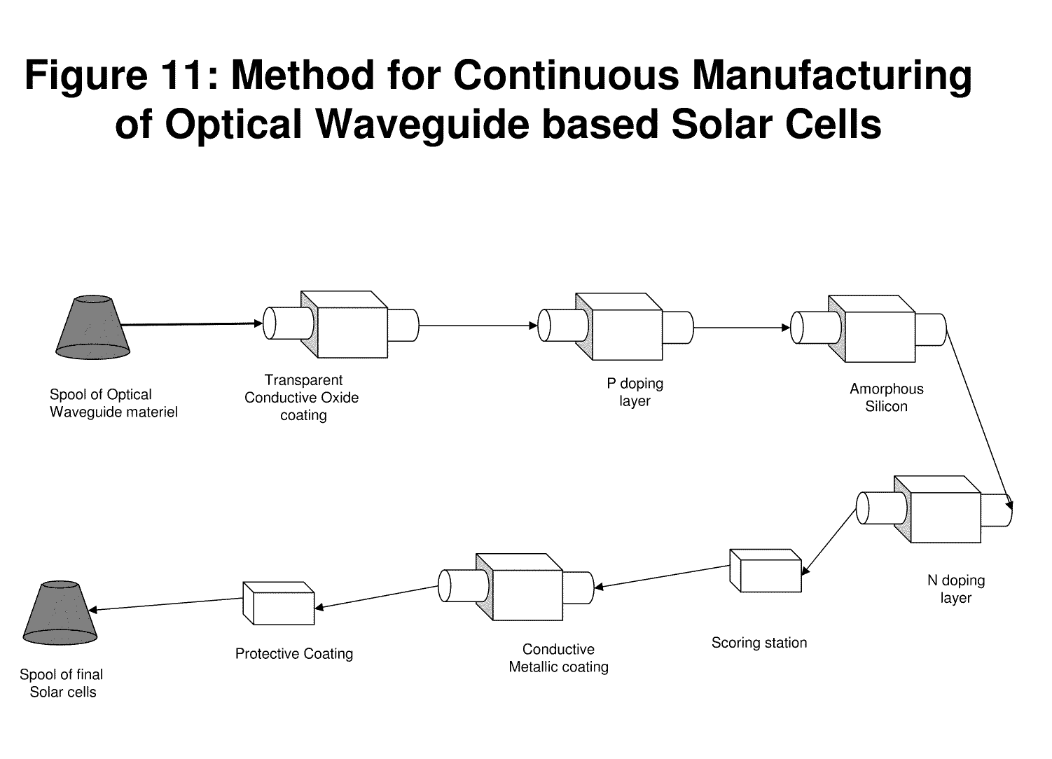

FIG. 11 shows a method of continuously manufacturing Optical Waveguide based Solar Cells that use thin film amorphous Silicon. An Optical Waveguide based thin film amorphous Silicon type Solar Cell could be manufactured in a continuous process by using a series of vacuum vapor deposition chambers each one which of which would lay down one layer of different material in series. Additional stations would perform the scoring and or cutting, the attachment of wire conductor and then finally the protective coating wrapping. This is an example of an Optical waveguide based Solar Cell that employs a single band of photovoltaic materiel. Multiple bands of photovoltaic material and multi junction photovoltaic layers, that are used to capture different energy bandgaps from the sunlight, could similarly be manufactured. In this latter scenario, additional stations would be added to the continuous manufacturing process. The exact station type would depend upon the optimal manufacturing process as well as the final Solar Cell design requirements. For example, the P-doping and N-doping layers could be changed in order. The process to coat Optical Waveguide equally could vary depending upon the requirements of manufacturing. For example, the final protective coating could be a metallic foil wrap instead of conductive metal molecules deposited directly onto the Optical Waveguide via a process of vapor deposition in a vacuum. Similarly, the use of an electroplating technique or a solution dip technique could be employed depending upon the manufacturing requirements of the materials used.

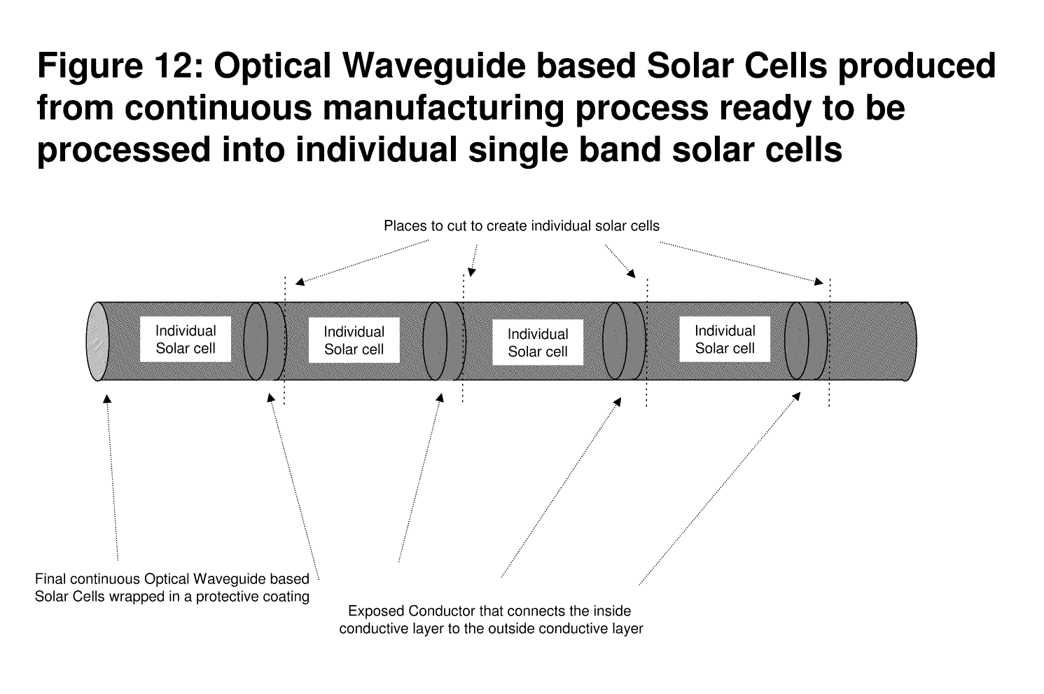

FIG. 12 shows an example of the output from the manufacturing process which is a long Optical Waveguide strand that has a number of individual Solar Cells along its length at regular intervals. The intervals are shown clearly by the conductive bands along the ends of the individual Solar Cells. These conductive bands are the exposed portion of outer layer of conductive material that is also connected to the inner conductive band at this point. This is the point where a conductive material can be connected, for example by using a metal wire, to extract the electricity from the photovoltaic circuit. The thickness of the Optical Waveguide and the length of the individual Solar Cells would be determined by the final product requirements. This spool of Optical Waveguide based Solar Cells could be processed further: woven into a fabric, impregnated with a resin, and cut to produce a final Solar Cell module or product in the form of composite type material. FIG. 12 shows the locations where the single banded Solar Cells start and end. The final manufacturing process would cut at these locations in a stage before final assembly. Note that the Optical Waveguide based Solar Cells can be kept intact as physical entity until the last stages of manufacturing. This could be an advantage in manufacturing.

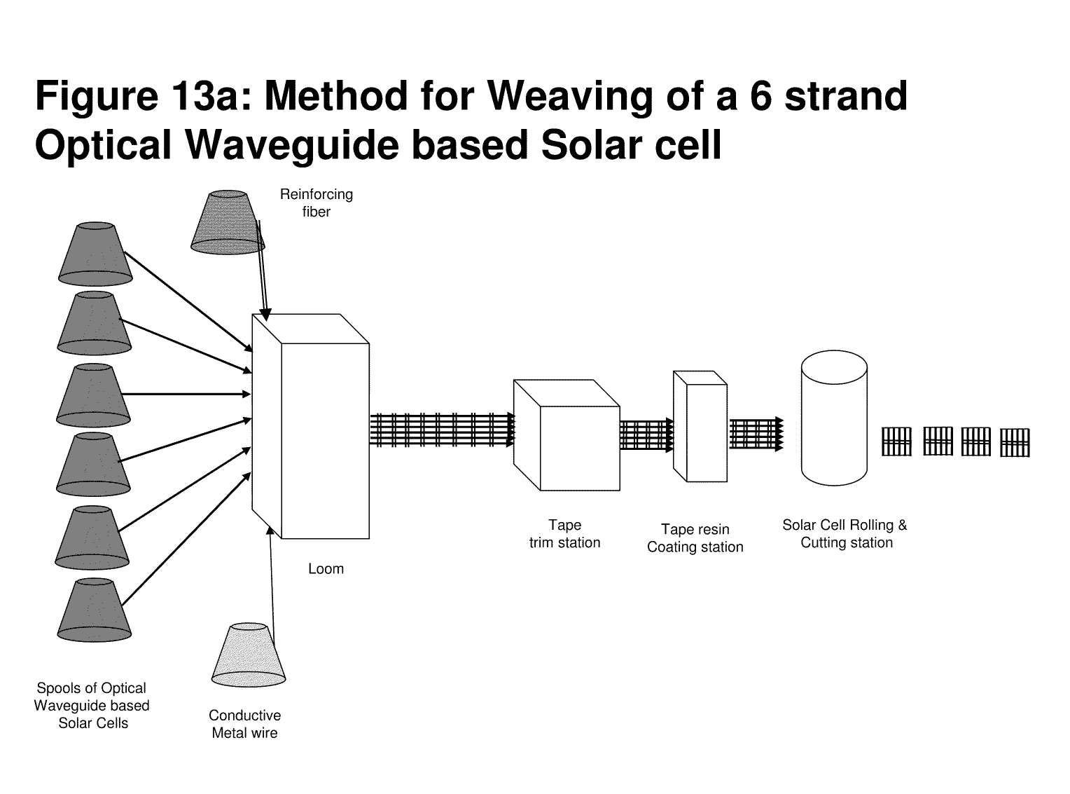

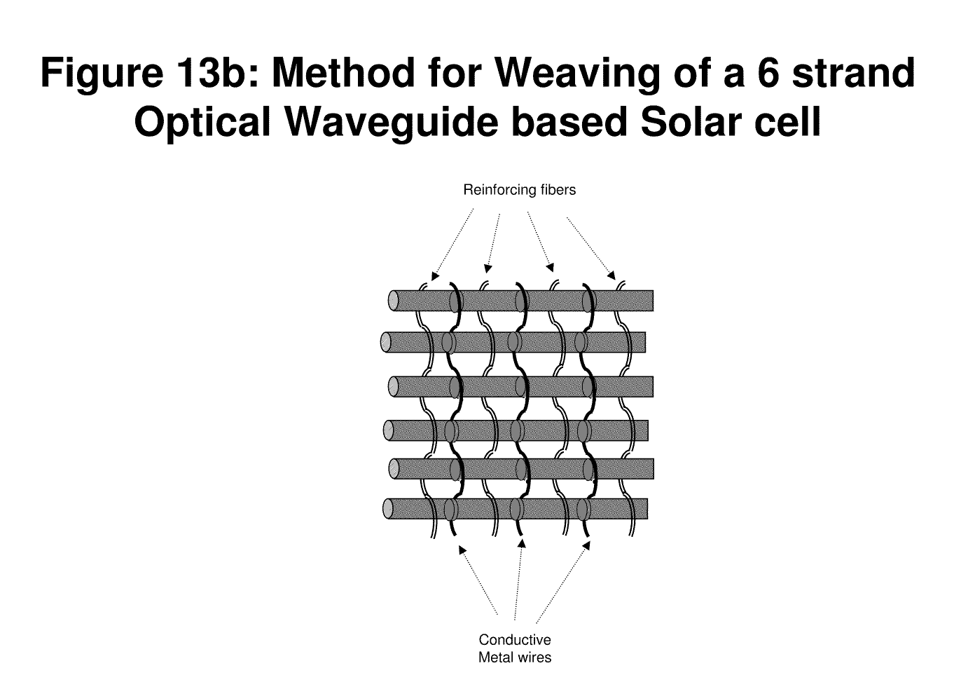

In FIGS. 13a and 13b shows an example of Optical Waveguide based Solar Cell strands being further manufactured to create a photovoltaic composite type fabric. The Optical Waveguides based Solar Cells would be combined with other strands of differing materials added for strength or conductivity such as those typically used in composite type materials used for high strength and low-weight applications such as aerospace structures. FIG. 13a shows a loom that is weaving 6 strands of single band type Optical Waveguide Based Solar Cells into a tape. Additionally strands of reinforcing fibers as well as conductive wires are being woven into the final tape. The tape would be variously trimmed to remove excess fibers, possibly coated or impregnated with a resin to bond the fibers together, and cut into final segments of Solar Cell units.

FIG. 13b shows an example of the output of the loom in FIG. 13a. The view is slightly exploded for clarity. The real tape would be tightly woven with little to no gaps showing between strands. This tape is shown woven with reinforcing fibers which could be carbon fibers added to increase the overall mechanical strength. This tape is also shown woven with conductive metal wires which intersect and connect with the exposed conductors on the individual Solar Cells. This is used to illustrate the manufacturing technique. More or less strands could be used depending upon the final Solar Cell design requirements.

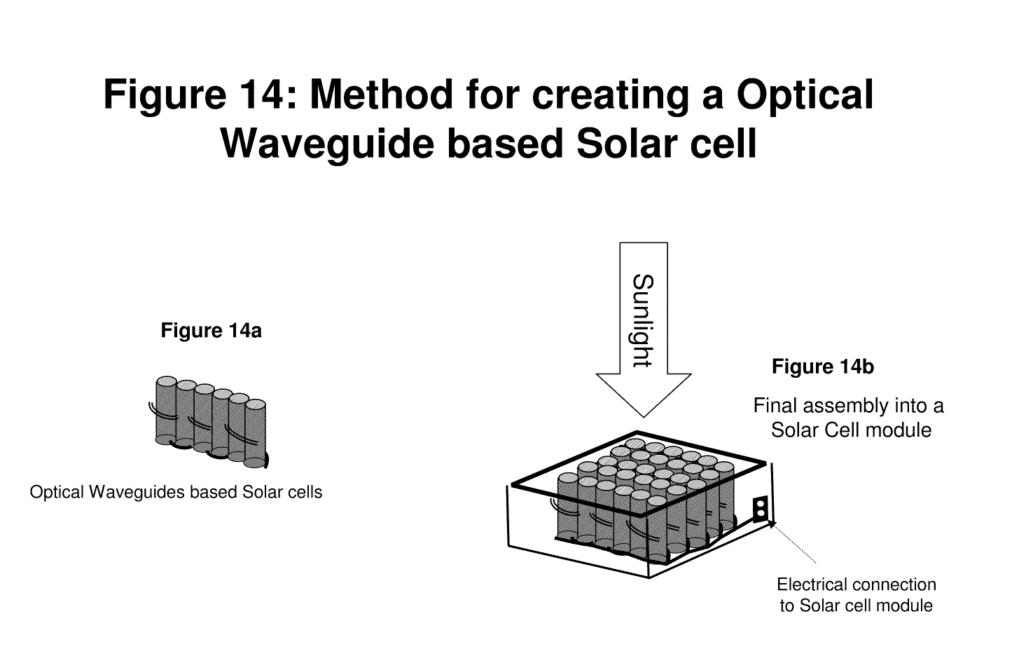

FIGS. 14a and 14b shows two possible examples of final Optical Waveguide based Solar Cell designs. In FIG. 14a the Optical Waveguide based Solar Cell strands would need to be cut where the individual photovoltaic solar cells are divided. The ends of the transparent ends of the Optical Waveguides exposed by the cutting process would need some a reflective surface added and some sort of protective covering.

The Optical Waveguide based Solar Cells would be combined create Solar Cell modules as shown in FIG. 14b. The final goal is a commercially useful Solar Cell module made up of high efficiency Optical Waveguide based Solar Cells. FIG. 14b shows one example of the final Solar Cell module which can be arrived at through different methods of manufacturing not confined solely to the long strand of Optical Waveguide based Solar Cells forming a continuous strand that was shown in FIG. 11 or in FIG. 13.

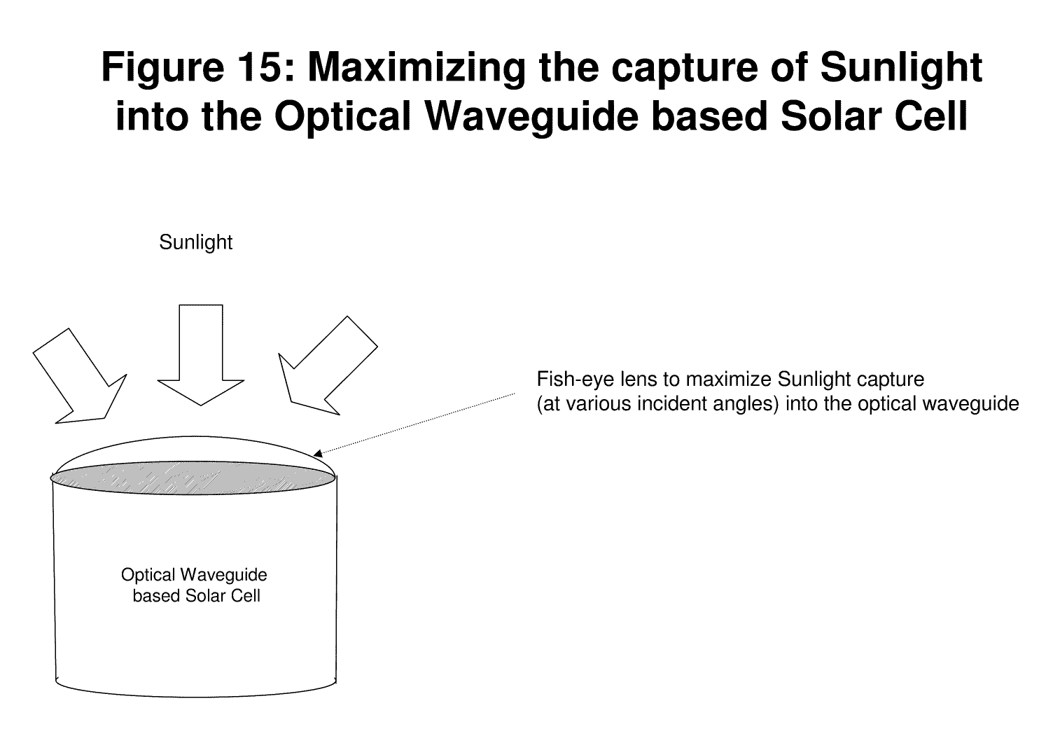

FIG. 15 is an example of treatment to, or covering on, the transparent end of the Optical Waveguide based Solar Cell. The purpose of using fisheye type lens is to capture light striking the end of the Optical Waveguide at different incident angles. It should improve the overall performance of the Solar Cell in certain applications such as a non-tracking type of Solar Cell module that is exposed to Sunlight at different angles throughout the day.

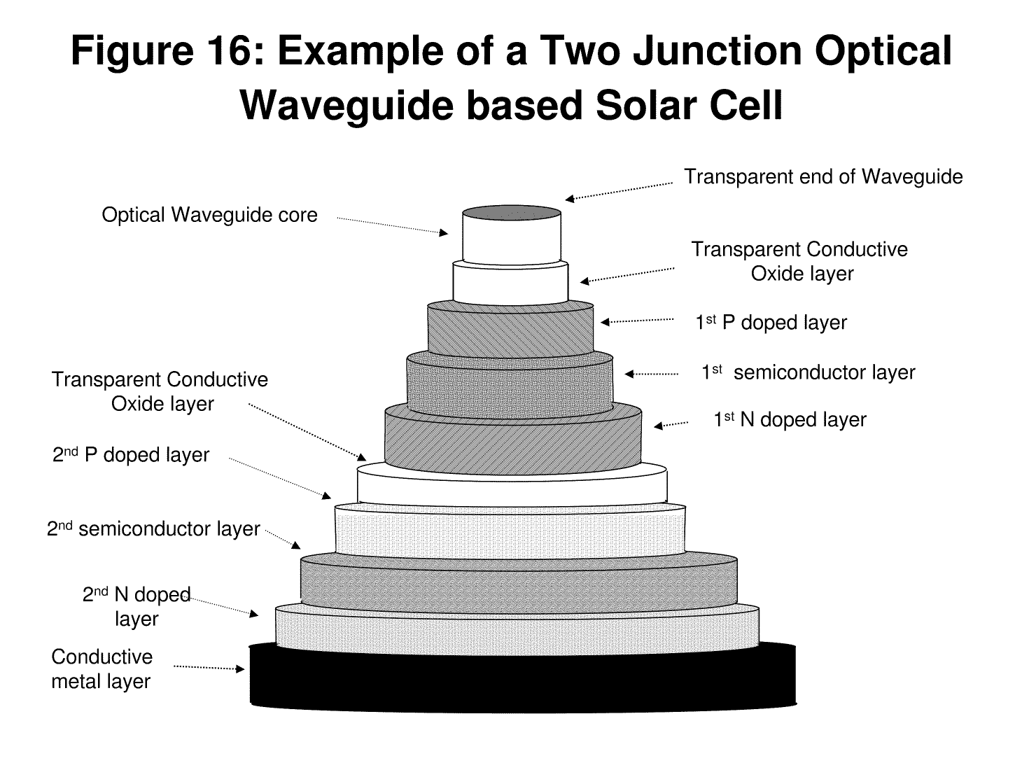

FIG. 16 shows an example of an Optical Waveguide based Solar Cell employing two junction thin film photovoltaic materials. The same technology that is used to create a two junction or multijunction photovoltaic cell can be applied to the band of photovoltaic material rapped around the Optical Waveguide. The choice of photovoltaic semiconductor materials could be any of those currently in use for thin film multijunction solar cells. An Optical Waveguide based multijunction Solar Cell design would be made more efficient in the conversion of Sunlight into electricity because it would use two different photovoltaic semiconductors each with different energy bandgaps. This would result in the conversion into electricity of more of the energy contained within the broad spectrum of Sunlight.

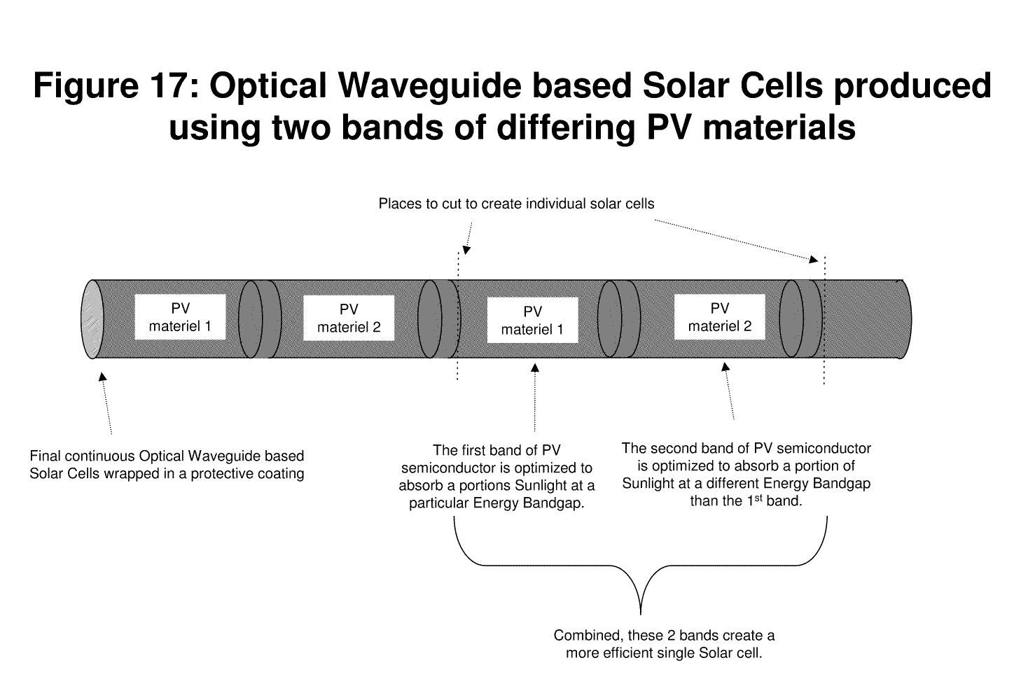

FIG. 17 shows a shows an example of the output from the strand manufacturing process used to produce a dual banded Optical Waveguide based Solar Cell. Similar to the design of a single banded Solar Cell design described in FIG. 12, the intervals are shown clearly by the conductive bands along the ends of the individual Solar Cells. These conductive bands are the exposed portion of outer layer of conductive material that is also connected to the inner conductive band at this point. This is the point where a conductive material can be connected, for example by using a metal wire, to extract the electricity from the photovoltaic circuit. FIG. 17 shows the locations where the dual banded Solar Cells start and end. The final manufacturing process would cut at these locations in a stage before final assembly.

The two bands are composed of different photovoltaic semiconductors each with unique energy bandgap properties. Similar in concept to a multijunction thin film type Solar Cell, the purpose of these two bands of photovoltaic materiel is to convert different portions of the Sunlight's spectrum into electricity thus creating a higher efficiency Solar Cell. Where the dual band Optical Waveguide based Solar Cell differs from an multijunction solar cell is that the layers of photovoltaic materiel are not layered on top of each other but rather exposed directly to the reflected light. The basic design limitation of a multijunction solar cell is the need to layer photovoltaic materials on top of each other causing the upper layers to obscure the lower layers and thus reducing their efficiency. The Optical Waveguide based Solar Cell capitalizes on the third dimension of depth to add multiple bands of different photovoltaic materiel which can each be directly exposed to the light without being obscured by the other photovoltaic materials.

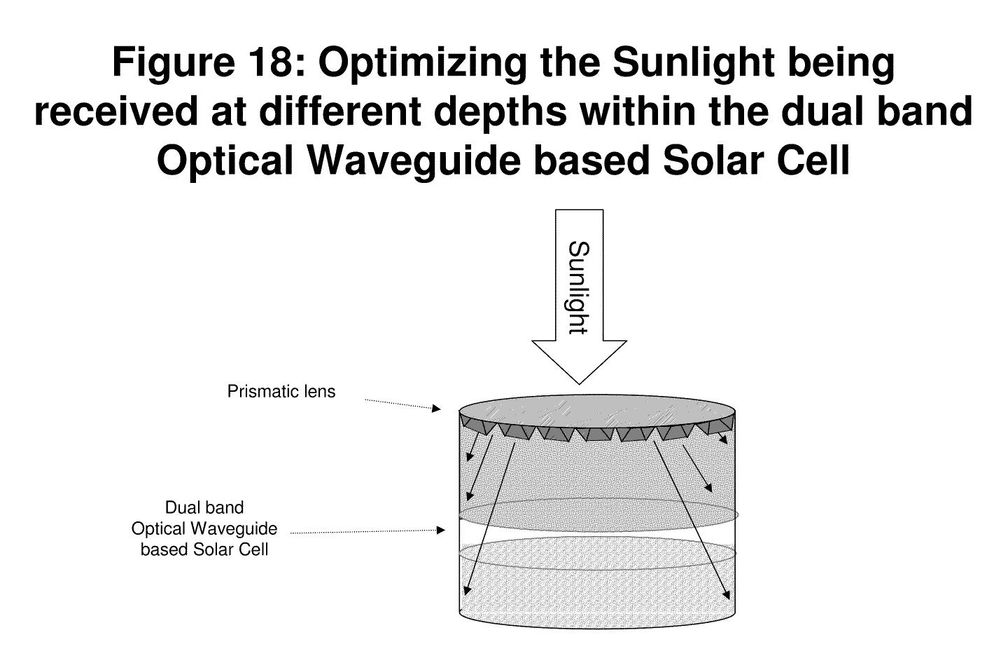

FIG. 18 shows an example of a prismatic lens on the transparent end of an Optical Waveguide based dual-banded Solar Cell. The purpose of prismatic lens is to focus light of different frequencies onto the two different bands of photovoltaic material that are at different depths within the Solar Cell. The prismatic lens would focus light of the optimal energy bandgap to the photovoltaic material optimized to convert it. The objective is to optimize the efficiency of the Solar Cell by converting all the energy in the sunlight.

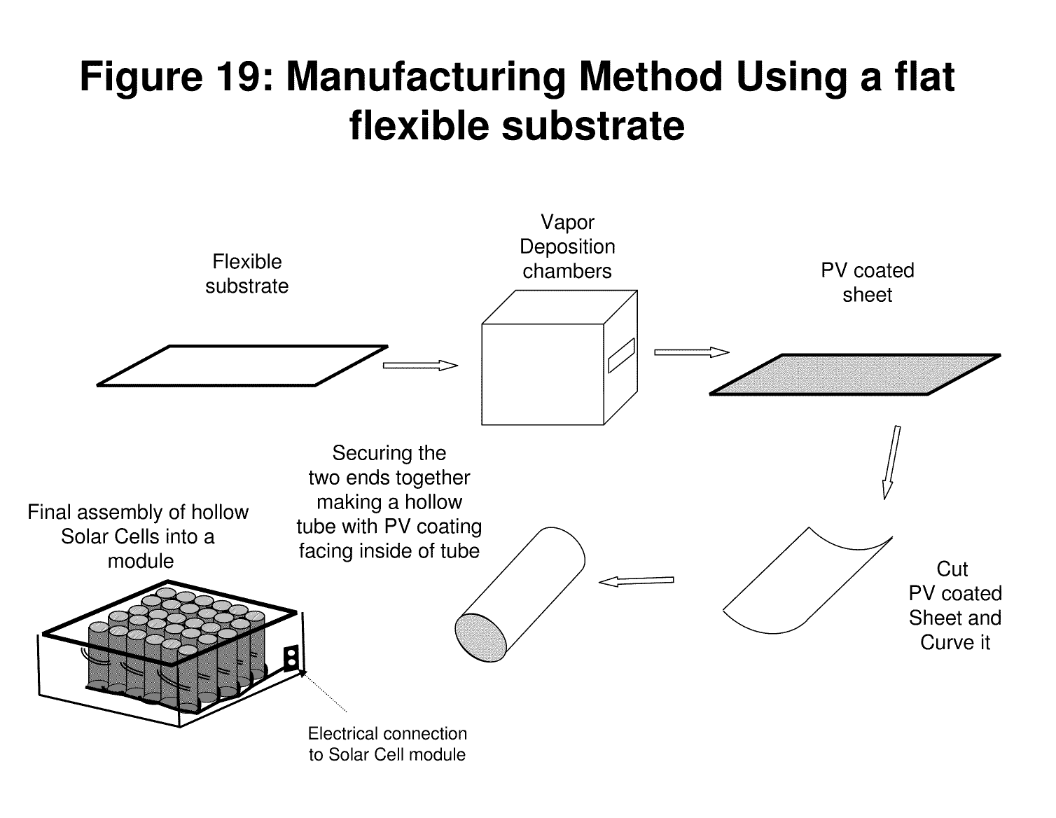

FIG. 19 shows a method of continuously manufacturing Optical Waveguide based Solar Cells that uses a flexible flat substrate. Similar to the process of manufacture described in FIG. 11, an Optical Waveguide based thin film type Solar Cell could be manufactured in a continuous process by using a series of vacuum vapor deposition chambers each one which of which would lay down one layer of different material in series onto a flat flexible substrate fed continuously through the machines as a tape. The final photovoltaic coated tape would be variously cut, coated with protective layers and then formed into a hollow cylindrical shape where the photovoltaic materiel is facing inwards. This hollow cylinder would act as an optical waveguide creating an Optical Waveguide based Solar Cell. The ends of the hollow cylinder would need to be covered with a protective cap one of which would be transparent to allow the entry of Sunlight into the Solar Cell. The individual hollow cylinders type Solar Cells would then be assembled in to a Solar Cell module.

While the invention has been particularly shown and described with reference to specific illustrative embodiments, it should be understood that various changes in form and detail may be made without departing from the spirit and scope of the invention as defined by the appended claims.

### INDUSTRIAL APPLICABILITY

The actual economics of using solar power versus alternate electrical power generation means varies due to circumstances and environment. There are a number of variables, not the least of which is the cost of fossil fuels, that will affect this complex equation. The availability of cheap high efficiency photovoltaic solar cells will lower the opportunity cost of using solar power versus competing sources of electricity. Other economic, political, and social variables will then play their parts in determining which source of electrical power generation is chosen for that place and time. With the use of this invention, the cost per kilowatt hour of photovoltaic solar cell produced electricity should be closer to that of fossil fuel based grid electricity. This will broaden the range of choices for power consumers.

A range of different solar cell type products designed for specific industrial applications is foreseen. The possible applications include use of the invention in Building Integrated Photovoltaic (BIPV), say in the form of a roofing tile made of composite materials plus Optical Waveguide based Solar Cells. Equally, aerospace structures could be manufactured using composite materials combined with Optical Waveguide based Solar Cells to provide lightness, strength, and electrical power.

The existing range of applications, currently served by solar cells, will benefit from the application of low-cost and high efficiency Optical Waveguide based Solar Cells.

### Novelty

The problems with solar cell inefficiency and high cost of manufacture that this invention helps solve, have been recognized in the industry for some time. The solution to the problem of solar cell efficiency by adding a third dimension of depth to solar cell has only been partially employed by a couple of technologies to date. These other technological approaches have been only partially successful because they only partially apply the third dimension of depth to solving the problem of solar cell efficiency.

One solution is the multijunction or heterojunction solar cell which adds at least a couple of layers of depth of differing photovoltaic materials in a attempt to capture all the energy in the Sunlight striking the solar cell. The multijunction approach is only partially effective since the sunlight has to pass through each intervening layer of material before it can strike the layer underneath. Even though these layers are very thin, they still obscure the layers beneath them and thus reduce the amount of energy in the light the strikes the lowest layers. The photovoltaic layers cannot be made very thick so this approach has finite limits.

Another approach, to capturing more of the energy in the sunlight striking a solar cell, involves using lenses to focus different frequencies, from the sunlight, onto different photovoltaic materials stacked in height. This approach was taken by Christiana Honsberg and Allen Barnett working at the University of Delaware and described in Forbes magazine. Effectively this creates three different solar cells stacked partially on top of each other. Setting aside, the complexities associated with focusing sunlight onto three different solar cells stacked one on top of the other, the original problem of the sunlight that is reflected back out of the solar cell, remains.

Unlike these two partial approaches to adding depth to a solar cell, the Optical Waveguide based Solar Cell takes full advantage of the third dimension of depth in solving the problems associated with photovoltaic solar cell efficiency.

The use of an optical fiber to deliver light to a photovoltaic cell on an electrical device has been claimed already (see U.S. Pat. No. 6,091,015 Jul. 18, 2000 del Valle et al. Photovoltaic energy supply system with optical fiber for implantable medical devices). This invention was focused on using an optical fiber to deliver light to a photovoltaic cell on a biomedical device implanted in a living organism. This particular invention did not claim that the photovoltaic cell was wrapped around the optical fiber nor did it claim to be creating a 3 Dimensional Solar Cell.

The use of photovoltaic fibers has been claimed already (see U.S. Pat. No. 6,913,713 Jul. 5, 2005 Chittibabu, et al. Photovoltaic fibers) but this invention has the photovoltaic material facing outwards from the fiber core which is not transparent. The problem with the photovoltaic material facing outwards from fiber core, is that it is the light must strike it coming in from the outside of the fiber. Any material woven with outward facing photovoltaic fibers will necessarily shade the light from much of the photovoltaic surfaces on the fiber. It is an fundamental problem, with all solar cell designs based upon semiconductors, that even small percentages of shading, on the solar cell, will significantly reduce the voltage produced by the solar cell. This problem is exacerbated because the photovoltaic effect, created by semiconductor materials, is low voltage to start. Any significant loss of voltage will rapidly degrade the solar cell circuit from being able to overcome the inherent resistance in the circuit and wire conductors used. The outward facing photovoltaic fibers efficiency in converting light into electricity is accordingly much lower than other commercially available crystalline silicon based solar cells.

The use of fiber based electric devices including that of photovoltaic was claimed in the United States Patent Application 2009/0103859 Shtein et al. Fiber-Based Electric Device published Apr. 23, 2009. As this is currently a patent application, it is not appropriate for this inventor to comment upon it in relation to the Optical Waveguide based Solar Cell.

The use of various types of semiconductor materials in a vast array of combinations has been discussed, published in technical literature, and patented. The invention of an Optical Waveguide based Solar Cell is not introducing an exotic new material to achieve a higher efficiency solar cell. This invention is taking full advantage of the cost effective solar cell technologies available today, for example thin film photovoltaic manufacturing, combined with a new geometry, to produce a significant increase in solar cell efficiency. The combination of existing photovoltaic materials in a new physical design is novel.

The use of a long strand of optical waveguide materiel, such as an optical fiber, is a manufacturing advantage since there are a number of existing wire based continuous manufacturing techniques which can applied to the cost effective manufacture of photovoltaic solar cells. The novelty lies in applying this existing knowledge of the manufacture of fiber based products such as composite materials to solar cells.

The use of numerous types of fibers used in composite material applications, that range from aerospace to sporting goods, is well known today. The novelty will be in combining the composites technology to a new Optical Waveguide based Solar Cell that can used in a directly a create a standalone Solar Cell module or used indirectly by being incorporated into a structural application such as a BIPV panel.

The use of additional devices to concentrate sunlight or to change its incoming incident angle is not obviated by this new design. For example, a solar concentration device, that uses reflective surfaces to concentrate sunlight onto a classic crystalline Silicon solar cell, could be effectively employed on an Optical Waveguide based Solar Cell.

What I claim:

1. An optical waveguide based solar cell comprising:
an optical waveguide;
an inwards facing solar cell.

2. The optical waveguide based solar cell of claim 1, wherein said optical waveguide can be made of glass, or any other transparent material, or may be hollow in shape.

3. The optical waveguide based solar cell of claim 1, wherein a variable thickness and depth of said solar cell may be employed.

4. The optical waveguide based solar cell of claim 1, wherein said solar cell can be manufactured into a variety of three dimensional geometric shapes.

5. The optical waveguide based solar cell of claim 1, wherein said solar cell, can be made of any materiel producing a photovoltaic effect.

6. The optical waveguide based solar cell of claim 1, wherein said solar cell, can completely cover the sides of said optical waveguide or cover only a portion of said optical waveguide.

7. The optical waveguide based solar cell of claim 1, wherein the interior surfaces of said optical waveguide, that are not covered with photovoltaic materiel, would comprise:
in part or in total a reflective surface or a refractive surface;
the means by which to direct the unconverted light towards the photovoltaic material, whereby the overall efficiency of said solar cell may be increased.

8. The optical waveguide based solar cell of claim 1, wherein the height and the thickness of the photovoltaic material will vary.

9. The optical waveguide based solar cell of claim 1, wherein the first layer, immediately adjacent to said optical waveguide, comprises:
a materiel which is both conductive and transparent to light;
and a means by which to complete an electrical circuit within said solar cell.

10. The optical waveguide based solar cell of claim 1, wherein the first layer, immediately adjacent to said optical waveguide may be comprised:
of a metal wire or a plurality of wires;
or a metallic mesh;
or a metal foil wrapped around said optical waveguide;
and a means by which to complete an electrical circuit within said solar cell.

11. The optical waveguide based solar cell of claim 1, wherein said metal conductor would comprise:
a highly reflective surface;
and a means by which the light, striking said metal conductor, would be reflected back into said optical waveguide whereby said reflected light might then be available for conversion to electricity upon striking said solar cell in a different location and thus increasing the overall efficiency of said solar cell.

12. The optical waveguide based solar cell of claim 1, wherein the layer that rests on the outside of said photovoltaic materials, comprises:
a conductive material;
and a means to complete the electrical circuit to the innermost conductive layer of said solar cell.

13. The optical waveguide based solar cell of claim 1, wherein an outermost layer of said solar cell, comprises:
a reflective materiel;
and a means to reflect unconverted light back into said solar cell whereby the unconverted light might have a further opportunity to be converted into electricity elsewhere within said solar cell thus increasing the efficiency of said solar cell.

14. The optical waveguide based solar cell of claim 1, wherein the end of said optical waveguide, that is used to capture light entering the solar cell, is to be made reflective in one direction so as to reflect light back into the solar cell whereby said reflected light might have a further opportunity to be converted into electricity elsewhere within said solar cell and thus increasing the efficiency of said solar cell.

15. A method of increasing the efficiency of a solar cell which receives light at different angles of incidence throughout its operating cycle comprising:
a fisheye type lens that is placed on the end of said optical waveguide based solar cell;
and a means by which light at higher angles of incidence to the end of said optical waveguide would be then captured whereby increasing the efficiency of said solar cell throughout the day.

16. The optical waveguide based solar cell of claim 1, wherein a multijunction type solar cell would be used whereby more of the energy from different energy bandgaps of the light captured within said solar cell, would be converted thus increasing the overall efficiency of said solar cell.

17. The optical waveguide based solar cell of claim 1, wherein more than one type of photovoltaic material will be banded along the length of said optical waveguide, whereby more of the energy from the different energy bandgaps of the light captured within said solar cell, would be converted thus increasing the overall efficiency of said solar cell.

18. A method of increasing the efficiency of an optical waveguide based solar cell with multiple bands comprising:
a prismatic type lens placed on the end of the optical waveguide;
and a means by which to direct different portions of the spectrum of light towards different depths into said solar cell whereby the spectrum of light, corresponding to the optimal energy bandgap of said bands of different photovoltaic materiel, would be optimized thus increasing the efficiency of said solar cell.

19. A solar cell module comprising:
one or a plurality of optical waveguide based solar cells;
and a means to combine said solar cells into a three dimensional geometric shape;
and a means to electrically connect said solar cells into a circuit.

20. The solar cell module of claim 19, wherein said solar cells may be angled to the perpendicular from that of the optical waveguide end used to capture light, or the solar cells may be rotated through three dimensions resulting in a corkscrewed or spiraled shape whereby the thickness of said solar cell module might be reduced.

21. A method of continuous manufacture of the optical waveguide based solar cells compromising the steps of:
feeding a transparent strand of materiel, which forms said optical waveguide, into a station which first coats said strand with a transparent conductive layer;
three more stations which individually deposit a n layer, a semiconductor layer, and a p layer that compromise the photovoltaic materials;
a station which scores said strand and exposes said innermost transparent conductive layer;
a station which coats said strand with an outer conductive layer;
a station which wraps said strand with a protective covering leaving said conductive bands exposed at intervals along the strand.
These functional stations may be variously combined into single machines for ease of manufacture.

22. The method of continuous manufacturing of the optical waveguide based solar cells of claim 21, wherein the order of the steps maybe changed whereby said solar cells may be more easily manufactured.

23. The method of continuous manufacturing of the optical waveguide based solar cells of claim 21, wherein a plurality of said strands that feed into each station may be employed.

24. A method of manufacturing an optical waveguide based solar cell fabric comprising:
a strand of optical waveguide based solar cells;
and a means wherein said strands are woven into a fabric as part of the manufacturing process.

25. A method of manufacturing an optical waveguide based solar cell composite structural materiel, comprising;
an optical waveguide based solar cell fabric;
and a reinforcing fiber or plurality of said fibers;
and a means by which said composite materiel would have increased mechanical strength;
and a resin system;
and a means by which said fabric and said fibers would be bonded together.

26. A method of continuous manufacture of the optical waveguide based solar cell comprising the steps of:
feeding a flat flexible substrate into a station which coats said substrate with an outer conductive layer;
three more stations which individually deposit a n layer, a semiconductor, and a p layer that comprise the photovoltaic materials upon said substrate;
a station that coats said substrate with a transparent conductive layer;
and a means by which said flat flexible substrate, is cut and then shaped into a hollow tube which then forms the basis of an optical waveguide;
and a means by which said hollow optical waveguide based solar cells are secured into this shape whereby said hollow optical waveguide based solar cells may be more easily assembled into working solar cell modules.
These functional stations may be variously combined into single machines for ease of manufacture.
